(19) United States
(12) Patent Application Publication
(10) Pub. No.: US 2024/0403513 A1
(43) Pub. Date: Dec. 5, 2024

(54) KNOWLEDGE GRAPH RESPONSIVE GENERATION OF MODEL INTERCONNECTIONS AND NEW MODELS FOR DIGITAL TWIN OPTIMIZATION OF VESSEL EMISSIONS

(71) Applicant: Konnecta Systems IKE, Kifisia (GR)

(72) Inventors: Antonis Antonopoulos, Aghia Paraskevi (GR); Antonis Mygiakis, Chalandri (GR); Panayotis Katsoulakos, Haywards Heath (GB); Ioanna Fergadiotou, Ntrafi-Pikermi (GR)

(73) Assignee: Konnecta Systems IKE, Kifisia (GR)

(21) Appl. No.: 18/205,382

(22) Filed: Jun. 2, 2023

(51) Int. Cl. G06F 30/20

(52) U.S. Cl. CPC G06F 30/20

(57) ABSTRACT

Model generation for digital twin prediction of vessel emissions includes loading a knowledge graph of nodes into memory of a host computer. Each node of the knowledge graph encapsulates an identifier for a model representing a specific system or function of a vessel and different nodes specify axes to related nodes. Thereafter, a reasoner applied to the nodes infers additional axes between selected ones of the nodes. Subsequently, a model hierarchy is generated from the knowledge graph by parsing the knowledge graph to generate an entry in a data structure for each of the nodes, and also an entry indicating a parent or a child dependency upon another of the nodes, the data structure defining the model hierarchy for the vessel. Finally, a digital twin executes in the memory of the host computer and simulates vessel emissions for the vessel based upon values sensed or estimated for elements of the vessel modeled within the model hierarchy.

### BACKGROUND OF THE INVENTION

### Field of the Invention

The present invention relates to the technical field of operational and emissions modeling for vessels and more particularly to the generation of model pipelines to match operational realities of a vessel and which can be executed to control vessel operational performance and while achieving decarbonization goals.

### Description of the Related Art

Digitalized modeling in the form of digital twin technology has proven especially promising in the understanding and optimization of vehicles, from satellites, to automobiles and recently, ocean-going vessels. In simple terms, the digital twin of a vessel is a digital replica of the vessel in terms of its structure, equipment and functions, from the hull to the smallest sensor. Digital twins use bi-directional, communication links each with a communications interface of a corresponding onboard system or sensor in order to monitor and predict vessel performance and also to optimize vessel performance by executing models that trigger activation of appropriate actions on one or more elements of the vessel, either manually or automatically.

Digital twinning of a vessel then, is the process, data, models and platforms used to create a digital twin of the vessel itself. Data used to build the digital twin will need to be based on the digital twin models/schemas library. The models represent, typically, a hierarchical ship's functions structure, a library of components and interrelations between functions and components and can be interconnected via input/output variables. The digital twin models evolve with its physical counterparts and the two must always mirror one another. The communication link from the ship to the digital twin is used to constantly monitor the physical vessel through several data collection techniques and devices. The constant data collection from the sensors on board the vessel allows the digital twin to continuously learn from its physical counterpart, and to evolve throughout the lifecycle of the vessel. As a result, a digital twin can be used to gain insights into the current state of the vessel as well as to predict future states of the vessel through simulation or predictive algorithms. Finally, the digital twin can provide automated supervisory control of the physical ship or inform human decision makers who can perform appropriate tasks.

Modelling approaches for digital twins include both white box approaches based upon mathematical models that are derived theoretically and are validated empirically from experimental data, e.g., from towing tank or sea trials, or from actual operational data collection, and also black box approaches that utilize statistical techniques to derive the relationships between the digital twin data and could be used readily for new models generation as well as hybrid or ‘grey box’ models that combine the in order to decrease the error margin and give better prediction accuracy with reasonable computational time.

Central to the use of a digital twin in modeling a vessel, then, is the production of a model hierarchy of vessel functions of the vessel from its whole down to its systems and subsystems in between. Constructing a model hierarchy of vessel elements for use in digital twinning, however, requires substantial effort by a team of experts and can be an exhausting and tedious exercise in order to include all the constituent elements of the vessel, and the determination of the various and sundry interrelationships between those elements. Once the digital twin model library has emerged representing many thousands of elements, implementing a modification without disrupting the integrity of the overall ship model can be nearly impossible. Individual model refinements generated by AI capabilities of the digital twin are normally part of the system design.

However, there are two important types of changes that create significant challenges for the adoption of shipping digital twins. First, during the decarbonization transition, there will be frequent retrofitting of various decarbonization solutions reflected by new models that will become available through the industry dataspaces. Second, new regulatory and contractual obligations, as well as new good practices, should be reflected by new models in the digital twin.

### BRIEF SUMMARY OF THE INVENTION

Embodiments of the present invention address technical deficiencies of the art in respect to model hierarchy generation for digital twinning. To that end, embodiments of the present invention provide for a novel and non-obvious method for model generation for digital twin operational optimization with respect to vessel emissions. Embodiments of the present invention also provide for a novel and non-obvious computing device adapted to perform the foregoing method. Finally, embodiments of the present invention provide for a novel and non-obvious data processing system incorporating the foregoing device in order to perform the foregoing method.

In one embodiment of the invention, a model generation method for digital twin operational optimization with respect to prediction of vessel emissions includes loading a knowledge graph of nodes into memory of a host computer. Each of the nodes of the knowledge graph encapsulates an identifier for a model representing a specific system or function of a vessel and different nodes specify axes to related others of the nodes. In essence, the knowledge graph nodes represent models interconnected via inputs/output variables and an axis may be characterized by a variable common for the two nodes. Thereafter, a reasoner may be applied to the nodes in order to infer additional axes between selected ones of the nodes. Subsequently, the method includes generating a model hierarchy from the knowledge graph by parsing the knowledge graph to generate an entry in a data structure for each one of the nodes, and also an entry indicating a parent or a child dependency upon another of the nodes, the data structure defining the model hierarchy for the vessel. Finally, the method includes executing a digital twin in the memory of the host computer, with the digital twin simulating vessel emissions for the vessel based upon values sensed or estimated for elements of the vessel modeled within the model hierarchy.

In one aspect of the embodiment, the knowledge graph is changed by changing at least one of the nodes and a corresponding one of the axes and, in response, the model hierarchy is regenerated according to the changed knowledge graph. Consequently, the digital twin is re-executed with the regenerated model hierarchy. In another aspect of the embodiment, the simulation of emissions includes an application of a setting to one or more nodes of the model hierarchy affecting the estimation of an emissions value produced in operation of the vessel. The setting applied to the node corresponds to a possible state or setting of the equivalent vessels function or system. Further, in yet another aspect of the embodiment, the digital twin additionally simulates a cost of achieving the emissions value based upon an aggregation of cost values of the model hierarchy. Finally, in yet another aspect of the embodiment, a repetitive procedure is applied to define the proper settings of vessel functions and systems to minimize cost of achieving the emissions value.

In another embodiment of the invention, a data processing system is adapted for model generation for digital twin prediction of vessel emissions. The system includes a host computing platform of one or more computers, each with memory and one or processing units including one or more processing cores. The system also includes a digital twin executing in the memory and simulating vessel emissions for the vessel based upon values estimated or sensed for elements of the vessel modeled within a model hierarchy. The system yet further includes a knowledge graph of nodes stored in the memory, with each one of the nodes of the knowledge graph encapsulating an identifier for a model representing a specific system or function t of a vessel, and different ones of the nodes specifying axes to related others of the nodes. Finally, the system includes a model generation module having computer program instructions that are enabled while executing in the memory of at least one of the processing units of the host computing platform to apply a reasoner to the nodes to infer additional axes between selected ones of the nodes and to generate the model hierarchy from the knowledge graph by parsing the knowledge graph to generate an entry in a data structure for each one of the nodes, and also an entry indicating a parent or a child dependency upon another of the nodes, the data structure defining the model hierarchy for the vessel.

In this way, the technical deficiencies of the tedious process of the creation and modification of a model hierarchy are overcome owing to the automated generation of the model hierarchy from a knowledge graph, and the subsequent re-generation of the model hierarchy to account for changes in the knowledge graph reflective of changes in the underlying vessel modeled in the digital twin by the re-generated model hierarchy. Additional aspects of the invention will be set forth in part in the description which follows, and in part will be obvious from the description, or may be learned by practice of the invention. The aspects of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The accompanying drawings, which are incorporated in and constitute part of this specification, illustrate embodiments of the invention and together with the description, serve to explain the principles of the invention. The embodiments illustrated herein are presently preferred, it being understood, however, that the invention is not limited to the precise arrangements and instrumentalities shown, wherein:

FIG. 1 is a pictorial illustration reflecting different aspects of a process of model generation for digital twin prediction of vessel emissions;

FIG. 2 is a block diagram depicting a data processing system adapted to perform one of the aspects of the process of FIG. 1; and,

FIG. 3 is a flow chart illustrating one of the aspects of the process of FIG. 1.

### DETAILED DESCRIPTION OF THE INVENTION

Embodiments of the invention provide for model generation for digital twin prediction of vessel emissions. In accordance with an embodiment of the invention, data stored within a database corresponding to different operational elements of a vessel and the relationships therebetween. A reasoner infers additional relationships between the operational elements in order to produce a knowledge graph. The nodes of the knowledge graph are then mapped to corresponding nodes in a model hierarchy of the vessel with the nodes of the model hierarchy having a hierarchical arrangement according to the dependencies of the elements of each node with parent or children ones of the nodes. The model hierarchy is supplied to a digital twin to the operational elements of the vessel. The digital twin in turn simulates carbon emissions of the vessel according to the model hierarchy. Thereafter, changes to the operational elements represented in the database result in a reformulated knowledge graph which then triggers a re-generation of the model hierarchy for use by the digital twin in conducting the simulation of the vessel. In this way, the model hierarchy can be automatically generated and then subsequently modified based upon changes to the operational elements in the database from which the knowledge graph is based.

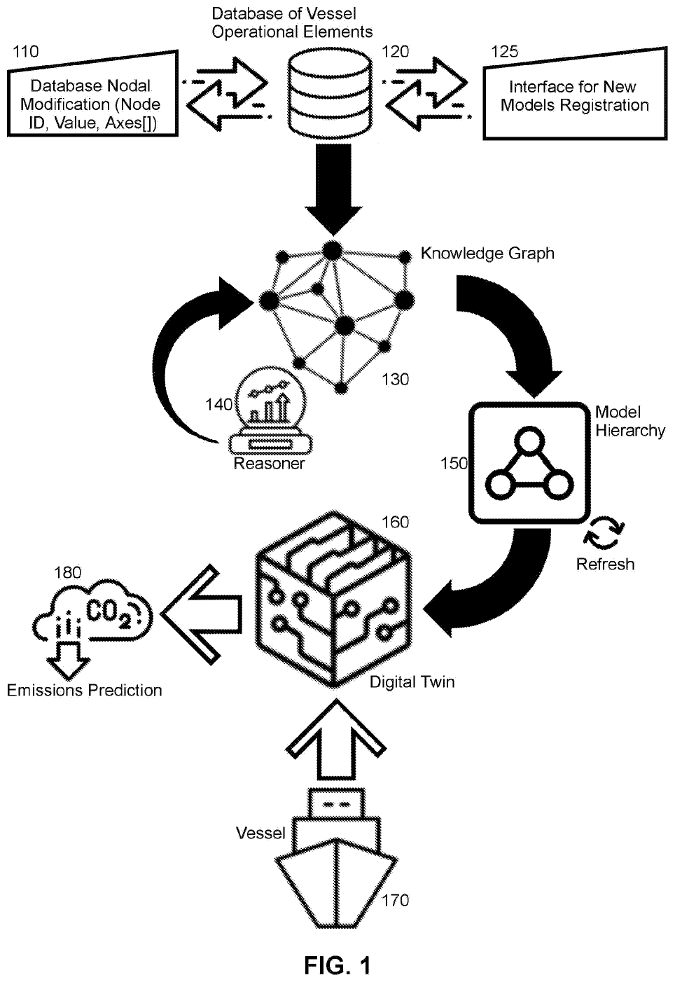

In illustration of one aspect of the embodiment, FIG. 1 pictorially shows a process of model generation for digital twin prediction of vessel emissions. As shown in FIG. 1, records in a database 120 of vessel operational elements include representative data of the operational elements of a vessel 170 along with a specification of the relationship between individual ones of the operational elements and zero or more other ones of the operational elements. The records are extracted from the database 120 to produce a basis for a knowledge graph 130 which is augmented by reasoner 140 adapted to infer additional relationships between ones of the operational elements and others of the operational elements. The nodes of the resulting knowledge graph 130 are then hierarchically arranged into a model hierarchy 150 that is submitted to a digital twin 160 mapped to the operational elements of the vessel 170. The digital twin 160 in turn simulates the model hierarchy 150 in order to produce an emissions prediction 180 for the vessel 170.

Subsequently, a database nodal modification 110 is applied to one or more records of the database 120, including either an addition to, a deletion from, or a change to one or more records of the database 120. Consequently, the knowledge graph 130 is reconstructed and then augmented by the reasoner 140. As such, the nodes of the reconstructed and augmented form of the knowledge graph 130 are hierarchically arranged into a new form of the model hierarch 150 which in turn is submitted to the digital twin 160. The digital twin 160 then simulates the model hierarchy 150 in order to produce a new emissions prediction 180 for the vessel 170.

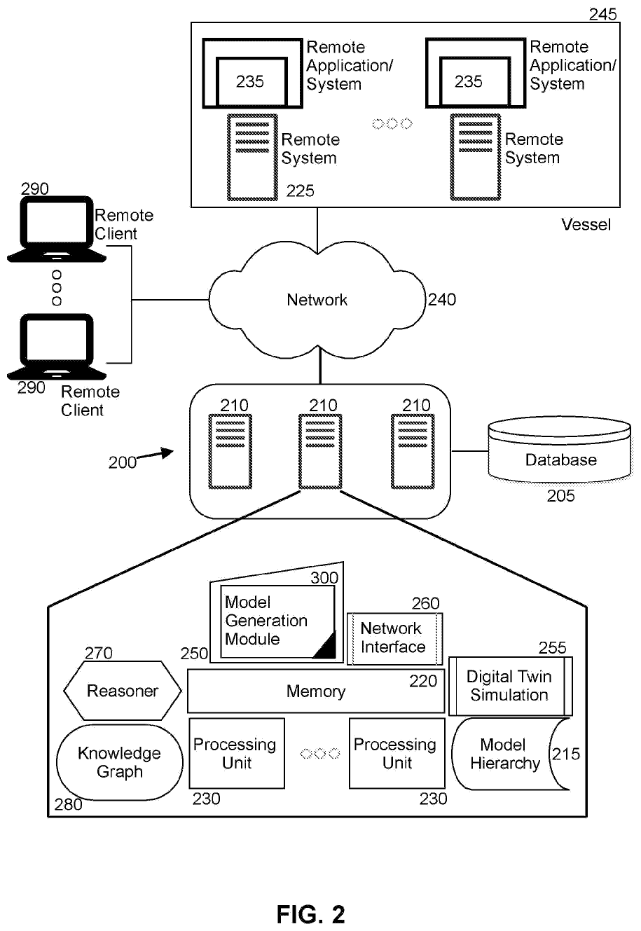

Aspects of the process described in connection with FIG. 1 can be implemented within a data processing system. In further illustration, FIG. 2 schematically shows a data processing system adapted to perform model generation for digital twin prediction of vessel emissions. In the data processing system illustrated in FIG. 1, a host computing platform 200 is provided. The host computing platform 200 includes one or more computers 210, each with memory 220 and one or more processing units 230. The computers 210 of the host computing platform (only a single computer shown for the purpose of illustrative simplicity) can be co-located within one another and in communication with one another over a local area network, or over a data communications bus, or the computers can be remotely disposed from one another and in communication with one another through network interface 260 over a data communications network 240.

A digital twin simulation 255 executes in the memory 220 by the processing units 230 on a model hierarchy 215 modeling the operational elements of remote systems 255 of a vessel 245, each of the operational elements of the remote systems 255 communicating with the digital twin simulation 255 between respective remote applications 235 over the data communications network 260 through the network interface 260. Notably, a computing device 250 including a non-transitory computer readable storage medium can be included with the data processing system 200 and accessed by the processing units 230 of one or more of the computers 210. The computing device stores 250 thereon or retains therein a program module 300 that includes computer program instructions which when executed by one or more of the processing units 230, performs a programmatically executable process for model generation for digital twin prediction of vessel emissions.

Specifically, the program instructions during execution map a knowledge graph 280 based upon records of the operational elements in the database 205 and augmented by relationships inferred by reasoner 270, to the nodes of the model hierarchy 215. In this regard, each of the records in the database 205 define an operational element of the vessel 245 including the remote systems 225. Each of the records additionally specifies a relationship with zero or more other operational elements having corresponding others of the records. The records of the database 205 are then organized into nodes of the knowledge graph 280 reflecting the relationships between each of the nodes and zero or more others of the nodes along axes of relationships. Further, the reasoner 270 processes the records to infer additional relationships between the nodes. Each of the nodes of the knowledge graph 280 are then mapped into a hierarchical position of the model hierarchy 215.

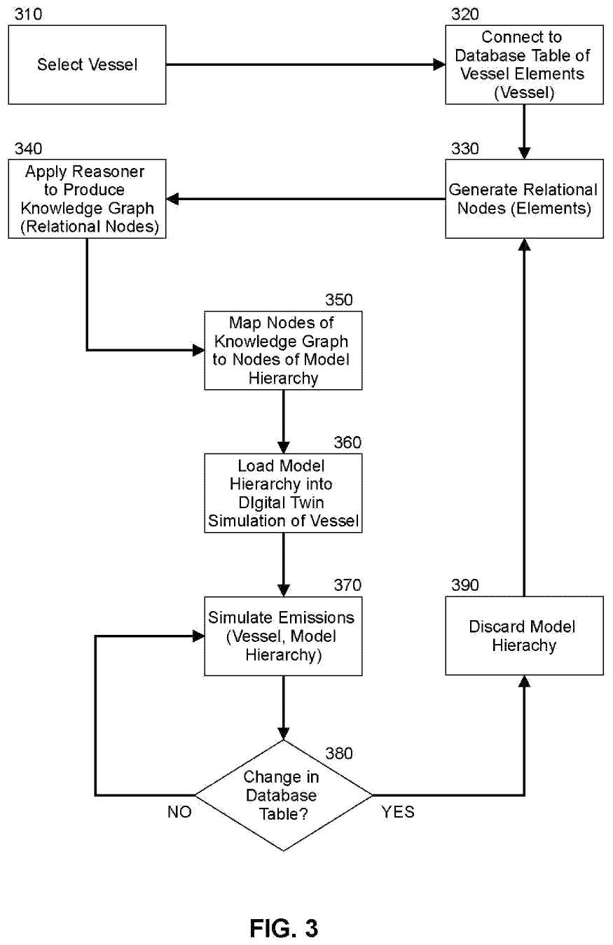

In further illustration of an exemplary operation of the module, FIG. 3 is a flow chart illustrating one of the aspects of the process of FIG. 1. Beginning in block 305, a vessel is selected for modeling and in block 320, a communicative connection is established with a database table including records representative of the operational elements of the vessel. Then, in block 330, relational nodes are created in memory with each node corresponding to a different one of the records in the database. Finally, in block 340, a reasoner is applied to the relational nodes in order to infer additional relationships between selected ones of the nodes of the knowledge graph.

In block 350, each of the nodes of the knowledge graph is mapped to a corresponding position in a model hierarchy reflecting the parent-child relationships between the relational nodes of the knowledge graph. Then, in block 360, the model hierarchy is loaded into a digital twin for simulation of the emissions of the vessel. In block 370, the simulation of the vessel commences to estimate operational condition of every modeled system function concluding to produced emissions' estimation based upon the model hierarchy. In decision block 380, it is determined whether or not a change has occurred to one or more records of the database and inherently to the knowledge graph. If so, the model hierarchy is discarded in block 390 and the process returns to block 330 with the re-generation of the relational nodes based upon the elements in the records of the database. In this way, the model hierarchy is continuously re-generated whenever changes are applied to the knowledge graph.

Of import, the foregoing flowchart and block diagram referred to herein illustrate the architecture, functionality, and operation of possible implementations of systems, methods, and computing devices according to various embodiments of the present invention. In this regard, each block in the flowchart or block diagrams may represent a module, segment, or portion of instructions, which includes one or more executable instructions for implementing the specified logical function or functions. In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

More specifically, the present invention may be embodied as a programmatically executable process. As well, the present invention may be embodied within a computing device upon which programmatic instructions are stored and from which the programmatic instructions are enabled to be loaded into memory of a data processing system and executed therefrom in order to perform the foregoing programmatically executable process. Even further, the present invention may be embodied within a data processing system adapted to load the programmatic instructions from a computing device and to then execute the programmatic instructions in order to perform the foregoing programmatically executable process.

To that end, the computing device is a non-transitory computer readable storage medium or media retaining therein or storing thereon computer readable program instructions. These instructions, when executed from memory by one or more processing units of a data processing system, cause the processing units to perform different programmatic processes exemplary of different aspects of the programmatically executable process. In this regard, the processing units each include an instruction execution device such as a central processing unit or “CPU” of a computer. One or more computers may be included within the data processing system. Of note, while the CPU can be a single core CPU, it will be understood that multiple CPU cores can operate within the CPU and in either instance, the instructions are directly loaded from memory into one or more of the cores of one or more of the CPUs for execution.

Aside from the direct loading of the instructions from memory for execution by one or more cores of a CPU or multiple CPUs, the computer readable program instructions described herein alternatively can be retrieved from over a computer communications network into the memory of a computer of the data processing system for execution therein. As well, only a portion of the program instructions may be retrieved into the memory from over the computer communications network, while other portions may be loaded from persistent storage of the computer. Even further, only a portion of the program instructions may execute by one or more processing cores of one or more CPUs of one of the computers of the data processing system, while other portions may cooperatively execute within a different computer of the data processing system that is either co-located with the computer or positioned remotely from the computer over the computer communications network with results of the computing by both computers shared therebetween.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

Having thus described the invention of the present application in detail and by reference to embodiments thereof, it will be apparent that modifications and variations are possible without departing from the scope of the invention defined in the appended claims as follows:

We claim:

1. A model generation method for digital twin prediction of vessel emissions, the method comprising:
loading a knowledge graph of nodes into memory of a host computer, each one of the nodes of the knowledge graph encapsulating an identifier for a model representing a specific system or function of a vessel, different ones of the nodes specifying axes to related others of the nodes;
applying a reasoner to the nodes to infer additional axes between selected ones of the nodes;
generating a model hierarchy from the knowledge graph by parsing the knowledge graph to generate an entry in a data structure for each one of the nodes, and also an entry indicating a parent or a child dependency upon another of the nodes, the data structure defining the model hierarchy for the vessel; and,
executing a digital twin in the memory of the host computer, the digital twin simulating vessel emissions for the vessel based upon values sensed or estimated for elements of the vessel modeled within the model hierarchy.

2. The method of claim 1, further comprising:
changing the knowledge graph by changing at least one of the nodes and a corresponding one of the axes;
regenerating the model hierarchy according to the changed knowledge graph; and,
re-executing the digital twin with the regenerated model hierarchy.

3. The method of claim 1, wherein the simulation of emissions comprises an application of a setting to one or more nodes of the model hierarchy affecting the estimation of an emissions value produced in operation of the vessel.

4. The method of claim 3, wherein the digital twin additionally simulates a cost of achieving the emissions value based upon an aggregation of cost values of the model hierarchy.

5. A data processing system adapted for model generation for digital twin prediction of vessel emissions, the system comprising:
a host computing platform comprising one or more computers, each with memory and one or processing units including one or more processing cores;
a digital twin executing in the memory and simulating vessel emissions for the vessel based upon values sensed or estimated for elements of the vessel modeled within a model hierarchy;
a knowledge graph of nodes stored in the memory, each one of the nodes of the knowledge graph encapsulating an identifier for a model representing a specific system or function of a vessel, different ones of the nodes specifying axes to related others of the nodes; and,
a model generation module comprising computer program instructions enabled while executing in the memory of at least one of the processing units of the host computing platform to perform:
applying a reasoner to the nodes to infer additional axes between selected ones of the nodes; and,
generating the model hierarchy from the knowledge graph by parsing the knowledge graph to generate an entry in a data structure for each one of the nodes, and also an entry indicating a parent or a child dependency upon another of the nodes, the data structure defining the model hierarchy for the vessel.

6. The system of claim 5, wherein the program instructions further perform:
changing the knowledge graph by changing at least one of the nodes and a corresponding one of the axes;
regenerating the model hierarchy according to the changed knowledge graph; and,
re-executing the digital twin with the regenerated model hierarchy.

7. The system of claim 5, wherein the simulation of emissions comprises an application of a settings to one or more nodes of the model hierarchy affecting the estimation of an emissions value produced in operation of the vessel.

8. The system of claim 7, wherein the digital twin additionally simulates a cost of achieving the emissions value based upon an aggregation of cost values of the model hierarchy.

9. A computing device comprising a non-transitory computer readable storage medium having program instructions stored therein, the instructions being executable by at least one processing core of a processing unit to cause the processing unit to perform model generation method for digital twin prediction of vessel emissions by:
loading a knowledge graph of nodes into memory of a host computer, each one of the nodes of the knowledge graph encapsulating an identifier for a model representing a specific system or function of a vessel, different ones of the nodes specifying axes to related others of the nodes;
applying a reasoner to the nodes to infer additional axes between selected ones of the nodes;
generating a model hierarchy from the knowledge graph by parsing the knowledge graph to generate an entry in a data structure for each one of the nodes, and also an entry indicating a parent or a child dependency upon another of the nodes, the data structure defining the model hierarchy for the vessel; and,
executing a digital twin in the memory of the host computer, the digital twin simulating vessel emissions for the vessel based upon values sensed or estimated for elements of the vessel modeled within the model hierarchy.

10. The device of claim 9, wherein the program instructions further cause the processing unit to perform:
changing the knowledge graph by changing at least one of the nodes and a corresponding one of the axes;
regenerating the model hierarchy according to the changed knowledge graph; and,
re-executing the digital twin with the regenerated model hierarchy.

11. The device of claim 9, wherein the simulation of emissions comprises an application of a settings to one or more nodes of the model hierarchy affecting the estimation of an emissions value produced in operation of the vessel.

12. The device of claim 11, wherein the digital twin additionally simulates a cost of achieving the emissions value based upon an aggregation of cost values of the model hierarchy.
